(19) United States
(12) Patent Application Publication
(10) Pub. No.: US 2024/0352584 A1
(43) Pub. Date: Oct. 24, 2024

(54) NON-AXISYMMETRIC GAS DIFFUSER FOR PLASMA ENHANCED CHEMICAL VAPOR DEPOSITION

(71) Applicant: Applied Materials, Inc., Santa Clara, CA (US)

(72) Inventors: Yu-Hsuan WU, Tainan City (TW); Teng Mao WANG, Tainan City (TW); Yan-Chi PAN, Tainan City (TW); Yi-Jiun SHIU, Tainan City (TW); Jrjyan Jerry CHEN, Campbell, CA (US); Cheng-yuan LIN, Tainan City (TW); Hsiao-Ling YANG, Hsinchu (TW); Yu-Min WANG, Santa Clara, CA (US); Wen-Hao WU, San Jose, CA (US)

(21) Appl. No.: 18/618,937

(22) Filed: Mar. 27, 2024

Related U.S. Application Data
(60) Provisional application No. 63/460,825, filed on Apr. 20, 2023.

(51) Int. Cl. C23C 16/455

(52) U.S. Cl. CPC C23C 16/45559

(57) ABSTRACT

The present disclosure generally provides an apparatus and method for gas diffuser support structure for a vacuum chamber. The gas diffuser support structure comprises a backing plate having a central bore, and a gas deflector having a length and a width unequal to the length coupled to the backing plate by a plurality of outward fasteners coupled to a plurality of outward threaded holes formed in the backing plate, in which a spacer is disposed between the backing plate and the gas deflector, and in which a length to width ratio of the gas deflector is about 0.1:1 to about 10:1.

### CROSS-REFERENCE TO RELATED APPLICATION

This application claims benefit of U.S. Provisional Application No. 63/460,825, filed Apr. 20, 2023. The above-referenced application is incorporated herein by reference in its entirety.

### BACKGROUND

### Field

Embodiments of the present disclosure generally relate to a gas or plasma diffuser with a supporting structure for a plasma chamber.

### Description of the Related Art

Plasma enhanced chemical vapor deposition (PECVD) is a deposition method whereby processing gas is introduced into a processing chamber through a showerhead. The showerhead is electrically biased to ignite the processing gas into a plasma. A pedestal, sitting opposite to the showerhead, is electrically grounded and functions as an anode as well as a substrate support. The plasma of processing gases forms on or more films on the substrate.

The gas diffuser includes a gas deflector, which modifies one or more gas flow distributions. Conventionally, symmetrical gas deflectors have been used, in which the symmetric gas deflector provides limited uniformity and poor run-to-run consistency across a broad range of substrates. Additionally, gas deflectors suffer from plate deformation, further reducing uniformity and run-to-run consistency. Plate deformation warps the gas deflector such that gas flow distribution becomes inconsistent, prevents uniform film thickness deposition, and complicates cleaning procedures for the plasma chamber.

Therefore, what is needed is an improved gas deflector, and methods of using the same.

### SUMMARY

The present disclosure generally provides a gas diffuser support structure for a vacuum chamber. The gas diffuser support structure comprises a backing plate having a central bore, an integrated cross structure formed in the central bore, and a gas deflector having a length and a width that is different than the length coupled to the backing plate by a plurality of fasteners coupled to a threaded hole formed in the backing plate, in which a spacer is disposed between the backing plate and the gas deflector, and in which a length to width ratio of the gas deflector is about 0.1:1 to about 10:1.

The present disclosure also provides a gas diffuser support structure for a vacuum chamber having a backing plate having a central bore formed therein. A gas deflector having a length and a width that is different than the length is coupled to the backing plate by a plurality of fasteners coupled to a threaded hole formed in the backing plate, in which a length to width ratio of the gas deflector is about 0.1:1 to about 10:1.

The present disclosure also provides a gas diffuser support structure for a vacuum chamber having a backing plate made of an aluminum material and having a central bore formed therein. A cross structure is positioned in the central bore, in which the cross structure includes a plurality of spokes made of the aluminum material of the backing plate that separate a plurality of openings that are in fluid communication with the central bore. A gas deflector having a length and a width that is different than the length is coupled to the backing plate by a plurality of fasteners coupled to a threaded hole formed in the backing plate, in which a length to width ratio of the gas deflector is about 0.1:1 to about 10:1.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a schematic side cross-sectional view of one embodiment of a chamber, according to an embodiment of the disclosure.

FIG. 1B is a schematic cross-sectional view of one embodiment of a chamber having a gas deflector of the present disclosure, according to an embodiment of the disclosure.

FIG. 1C is a schematic cross-sectional view of one embodiment of a chamber having a gas deflector of the present disclosure, according to an embodiment of the disclosure.

FIG. 1D is a schematic cross-sectional view of one embodiment of a chamber having a gas deflector of the present disclosure, according to an embodiment of the disclosure.

FIG. 2A is a partial schematic sectional view of the chamber having a gas diffuser support assembly, according to another embodiment of the disclosure.

FIG. 2B is a partial sectional view of the gas deflector shown in FIG. 2A.

FIG. 2C is a partial schematic sectional view of a cover, according to an embodiment of the disclosure.

To facilitate understanding, identical reference numerals have been used, where possible, to designate identical elements that are common to the figures. It is also contemplated that elements and features of one embodiment may be beneficially incorporated on other embodiments without further recitation.

### DETAILED DESCRIPTION

The present disclosure generally provides a gas diffuser for a processing chamber. The disclosure will be described below in relation to a plasma enhanced chemical vapor deposition (PECVD) apparatus available from AKT America, Inc., a subsidiary of Applied Materials, Inc., Santa Clara, CA. It is to be understood that the disclosure has applicability in other deposition chambers as well, including deposition chambers and PECVD apparatus available from other manufacturers.

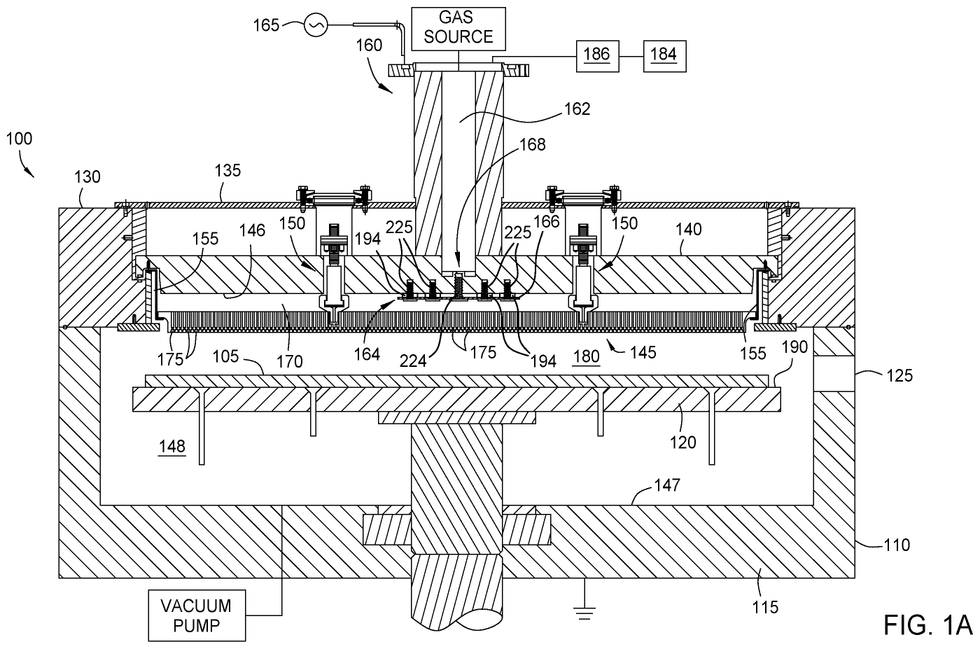

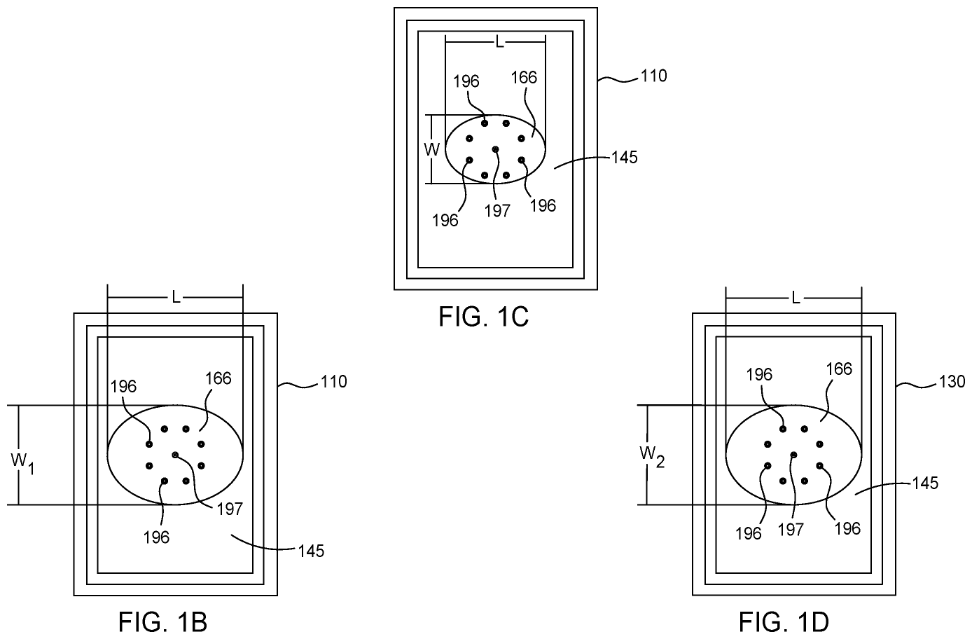

FIG. 1 is a schematic side cross-sectional view of one embodiment of a chamber 100. The chamber 100 is suitable for PECVD processes for fabricating circuitry, or performing other processes, on a large area substrate 105 made of glass, a polymer, or other suitable substrate. The chamber 100 is configured to form structures and devices on the large area substrate 105 for use in the fabrication of liquid crystal displays (LCD's) or flat panel displays, photovoltaic devices for solar cell arrays, or other structures. The structures may be a plurality of back channel etch inverted staggered (bottom gate) thin film transistors which may comprise a plurality of sequential deposition and masking steps. Other structures may include p-n junctions to form diodes for photovoltaic cells.

The chamber 100 includes a chamber sidewall 110, a bottom 115, a substrate support 120, such as a pedestal, which supports the large area substrate 105 during processing. The gas distribution showerhead 145 is positioned opposite the substrate support 120 and the large area substrate 105. The chamber 100 also has a port 125, such as a slit valve opening, that facilitates transfer of the large area substrate 105 into and out of the chamber 100 by selectively opening and closing. The chamber 100 also includes a lid structure 130, a backing plate 140, and a gas distribution showerhead 145. The lid structure 130 supports the backing plate 140 and the gas distribution showerhead 145. An interior surface 146 of the backing plate 140 and an interior surface 147 of the chamber sidewall 110 bounds a variable pressure region 148. In one aspect, the chamber 100 comprises a body which includes the chamber sidewall 110, the bottom 115 and the backing plate 140 bounding the variable pressure region 148. The backing plate 140 is sealed on its perimeter by suitable seals (e.g., o-rings) at interfaces where the backing plate 140 and the lid structure 130 may contact each other. The seals facilitate electrical insulation as well as seal the variable pressure region 148 when negative pressure is provided by a vacuum pump coupled to the chamber 100.

The gas distribution showerhead 145 is supported by the backing plate 140 at a central region thereof by one or more center support members 150. The one or more center support members 150 facilitate support of the gas distribution showerhead 145 at the central region of the gas distribution showerhead 145 to control the horizontal profile of the gas distribution showerhead 145 to mitigate the tendency of the gas distribution showerhead 145 to deform or sag due to one or a combination of heat, gravity and vacuum. The gas distribution showerhead 145 may also be supported at a perimeter thereof by a flexible suspension 155. The flexible suspension 155 is adapted to support the gas distribution showerhead 145 from edges of the gas distribution showerhead 145 and to allow lateral expansion and contraction of the gas distribution showerhead 145.

The chamber 100 is coupled to a gas inlet 160 that is coupled to a gas source and a plasma source 165. The plasma source 165 may be a direct current power source or a radio frequency (RF) power source. The RF power source may be inductively or capacitively coupled to the chamber 100. The gas inlet 160 delivers process from the gas source through a bore 162 to a gas diffuser assembly 164. The gas diffuser assembly 164 includes a perforated gas deflector 166. The gas deflector 166 is coupled to the backing plate 140 using a central fastener 224, and a plurality of outward fasteners 225 (e.g., screws), in which the central fastener 224 and each outward fastener of the plurality of outward fasteners 225 has a spacer 194. The spacer 194 forms a gap between the gas deflector 166 and the backing plate 140. The gas deflector 166 receives gases passing through the bore 162 from a gas baffle 168. The gas baffle 168 is integrated with the backing plate 140. In one example, the gas baffle 168 is a plurality of openings formed through the backing plate to facilitate fluid flow therethrough. The gas deflector 166 is fastened to a center of the gas baffle 168 by the central fastener 224. In one example, the central fastener 224 is integrally formed with the gas deflector 166, however, a separate gas deflector 166 and central faster 224 are contemplated. In addition, it is contemplated that the central fastener 224 may include a flared midsection 249. The flared midsection 249 facilitates securing of the central fastener 224 to the backing plate 140. In such an example, the flared midsection 249 has the same thickness as a spacer 194. It is contemplated that the flared midsection 249 may be an integral with the fastener, or may be removable therefrom (e.g., a nut).

The gas deflector 166 has a shape with an unequal length and width and/or is non-symmetrical and/or has dimensions which vary in different geometrical directions, e.g., oval, ellipsoidal, rhomboidal, square, triangular, pentagonal, hexagonal, heptagonal, octagonal, nonagonal, or the like. For example, and without limitation, the gas deflector 166 is ellipsoidal or oval; e.g., not circular. The area of the gas deflector 166 is about 3% to about 50% of the showerhead area. The gas deflector 166 has a length (l) and a width (w), as shown in FIGS. 1B-1D. The length (l) and the width (w) are different, in which the length and width are not equal. A length to width ratio may be from about 0.1:1 to about 10:1, e.g., from about 0.3:1 to about 3:1, from about 0.5:1 to about 1.5:1, from about 0.6:1 to about 1.33:1, or the like. For example, and without limitation, a ratio may be about 1.33:1 for a length (l) and a width (w₁), as shown in FIG. 1C. For example, and without limitation, a ratio may be about 1.5:1 for a length (l) and a width (w₂), as shown in FIG. 1D about 0.3:1, about 0.5:1, or the like. The length and width are not equal, in which the length to width ratio is not 1:1.

The length to width ratios noted herein provide a better flow uniformity on the whole substrate to be processed rather than just the center of the substrate, when the length and width are unequal. This provides a uniform coating of the substrate as the corners of the substrate become coated at a similar rate to the center of the substrate. The corner deposition rate allows for enhanced uniform deposition of a coating on a substrate compared to conventional circular gas deflectors.

The gas deflector 166 has a length of about 1 inch to about 30 inches, e.g., about 1 inch, about 5 inches, about 10 inches, about 15 inches, about 20 inches, about 25 inches, about 30 inches, or the like. The gas deflector 166 has a width of about 1 inch to about 30 inches, e.g., about 1 inch, about 5 inches, about 10 inches, about 15 inches, about 20 inches, about 25 inches, about 30 inches, or the like. For example, and without limitation, the gas deflector can have a length of about 15 inches and a width of about 10 inches. As a further non-limiting example, the gas deflector 166 can have a length of about 20 inches and a width of about 15 inches. It is contemplated, however, that other lengths and widths may be selected so long as the length and width are unequal.

The gas deflector 166 has an area of about 100 inches² to about 1,500 inches². For example, and without limitation, the area of the gas deflector 166 can be about 450-475 inches². As a further non-limiting example, the area of the gas deflector 166 can be about 925-975 inches². The gas deflector 166 has a thickness of about 0.001 inches to about 0.25 inches, e.g., about 0.1 inches to about 0.15 inches. For example, and without limitation, the gas deflector 166 has a thickness of about 0.125 inches.

The gas deflector has a center threaded hole 197, in which the center fastener 224 is received within the center threaded hole 197. The gas deflector 166 has a plurality of outward threaded holes 196 (shown in FIGS. 1B-1D), e.g., about 2 to about 20 threaded holes 196, e.g., about 2, about 3, about 4, about 5, about 6, about 7, about 8, about 9, about 10, about 11, about 12, about 13, about 14, about 15, about 16, about 17, about 18, about 19, about 20, or more. The outward threaded holes 196 can have a hole size of about 0.01 inches to about 1.0 inches, e.g., about 0.3 inches to about 0.6 inches. For example, and without limitation, the threaded holes 196 can have a hole size of about 0.4 inches, about 0.48 inches, or about 0.5 inches. While only 8 threaded holes are displayed in FIGS. 1B-1D, any number of fasteners and threaded holes may be included, as described herein. The outward threaded holes 196 are disposed in a circular pattern, equidistant from the center threaded hole 197 located at a center of the gas deflector 166. Outward fasteners 225 are received within the outward threaded holes 196 for securing the gas deflector 166 to a lower surface of the backing plate 140. In such an example, the gas deflector 166 is centrally aligned with the bore 162.

The shape of the gas deflector 166 described herein allows for enhanced uniform coating of the substrate compared to conventional circular gas deflectors. For example, and without limitation, an oval gas deflector provides improved thickness profiles of films deposited on a substrate. Without being bound by theory, it is believed that the unequal width and length dimensions of the gas deflector 166 compensates for components of the processing chamber which also have unequal widths and lengths. For example, one or more of the chamber body 110, the showerhead 145, or the back plate 140 may have unequal lengths and widths (e.g., rectangular in shape). Conventional symmetric gas diffusers distribute process gases symmetrically. Within a chamber having a width different than a length (e.g., rectangular), the symmetry of conventional gas deflector results in uneven gas flow in certain areas of the chamber (particularly the corners of the process volume relative to a center of the process volume), and thus, results in uneven deposition on a substrate. However, the shapes of the gas deflectors disclosed herein adequately account of process chamber asymmetries, improving deposition uniformity. Such uniformity is particularly improved in process chambers suitable for processing large area substrates, as the size of the chamber may exacerbate deposition uniformity when using symmetrical (e.g., circular) gas deflectors.

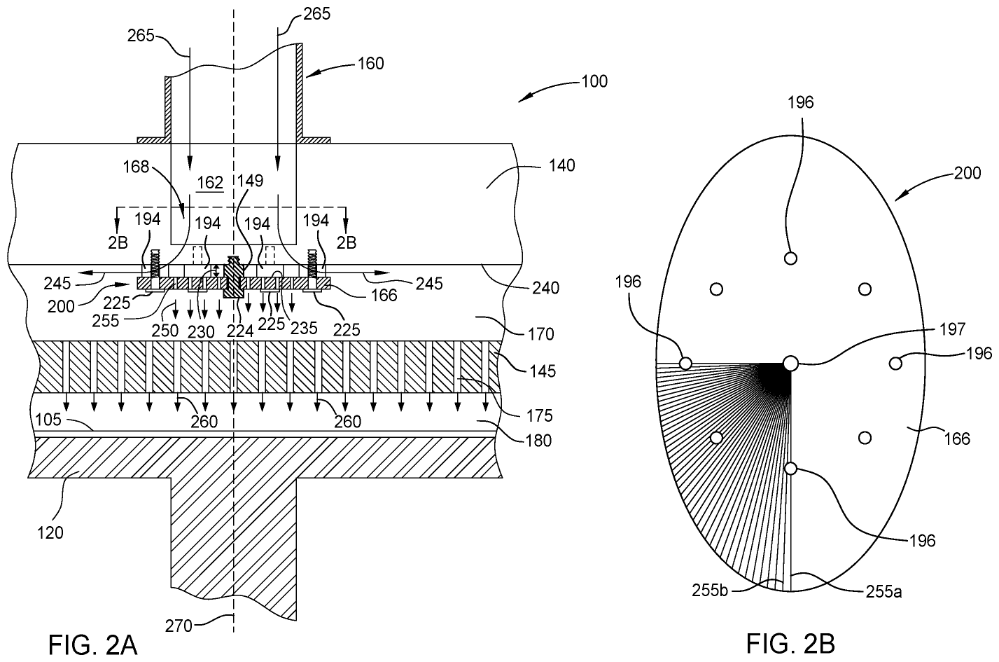

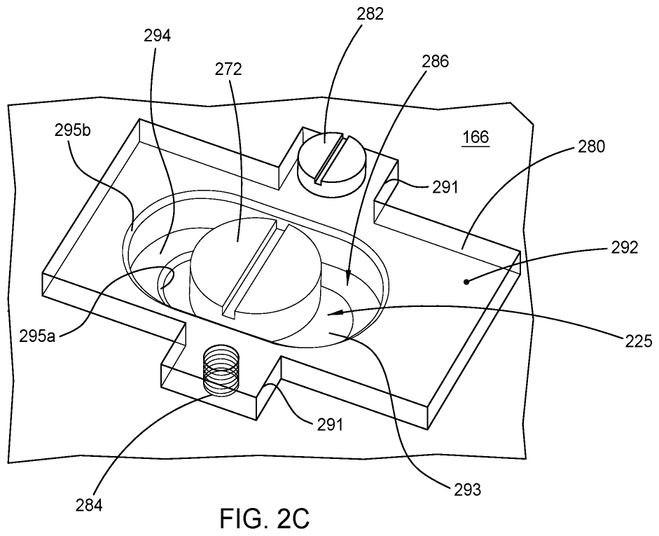

During processing, gases flow through the bore 162 to the gas baffle 168. The gasses flow through the gap 230 (shown in FIG. 2A), and reflect off the gas deflector 166 such that the gases are spread by the gas deflector 166 into an intermediate region 170 defined between the backing plate 140 and the gas distribution showerhead 145. The gas is deflected from the gas deflector 166 having an unequal length and width, such that an asymmetrical flow exists that spreads the gas to the corners of the substrate. This provides a uniform corner deposition rate, allowing for a uniform deposition of a coating on a substrate.

In operation, gases from the gas source of FIG. 1A or a plasma of cleaning gases from the remote plasma chamber 186 of FIG. 1A is flowed through the bore 162. The flow is provided along a conductance path through the gas baffle 168 into the intermediate region 170 defined between the backing plate 140 and the gas distribution showerhead 145. The conductance path includes multiple flow paths such as lateral flow paths around the gas deflector 166 and downward flow paths through a plurality of through-holes formed in the gas deflector 166. The spacing the and the size/pitch of the through-holes may be adjusted to achieve a predetermined gas distribution. A majority of gas flows along the lateral flow path, in which a majority is greater than 50% of the gas flowed along the conductance path. A minority of gas flows along the downward flow path through a plurality of through-holes, in which a minority is less than 50% of the gas flowed along the conductance path. The hole pitch and hole size described herein may be varied to vary the amount of gas flowing along the lateral flow path or vertical flow path. This provides control over the rate and location of deposition of a coating over a substrate by varying the amount of gas flowing along the later flow path and/or vertical flow path. The conductance path continues to the processing region 180 via flow paths 260 through the gas passages 175 formed through the gas distribution showerhead 145.

FIG. 2A is a partial schematic sectional view of the chamber 100 having a gas diffuser support assembly 200 in accordance with one embodiment of the disclosure. The gas diffuser support assembly 200 comprises the gas baffle 168 formed integrally in the backing plate 140 and the gas deflector 166 secured thereto with a center fastener 224 and a plurality of outward fasteners 225, e.g., screws. The gas deflector 166 substantially blocks or redirects the majority of a vertical downward gas or plasma flow 265, e.g., more than about 50% of the vertical downward gas or plasma flow 265 such as about 50%, about 60%, about 70%, about 80%, about 90%, or the like, from the bore 162 and generates lateral flow paths 245 that are substantially horizontal, which are substantially parallel to the backing plate 140 and the gas distribution showerhead 145.

As shown in FIG. 2A, the gas deflector 166 is coupled to the backing plate 140 by a plurality of outward fasteners 225 e.g., about 2 to about 20 fasteners, e.g., about 2, about 3, about 4, about 5, about 6, about 7, about 8, about 9, about 10, about 11, about 12, about 13, about 14, about 15, about 16, about 17, about 18, about 19, about 20, or the like. The center fastener 224 couples to center threaded hole 197 (shown in FIG. 2B). The plurality of outward fasteners 225 are a bolt or screw, such as a shoulder screw having a head. The plurality of outward fasteners 225 couple to outward threaded holes 196 (shown in FIG. 2B). While only a limited number of outward fasteners are shown in FIGS. 2A and 2B, any number of fasteners and threaded holes may be included, as described herein.

A spacer 194 made from one or more polymeric materials, e.g., tetrafluoroethylene, maintains a gap 230 between an upper surface 235 of the gas deflector 166 and a lower surface 240 of the backing plate 140. Each outward fastener of the plurality of outward fasteners 225 includes the spacer 194 such that the gap 230 is uniform between the backing plate 140 and the gas deflector 166. The gap 230 (between the backing plate 140 and the gas deflector 166) is between about 0.1 inches to about 1 inch, e.g., about 0.1 inches to about 0.75 inches, about 0.1 inches to about 0.5 inches, about 0.15 inches to about 0.3 inches, or the like. For example, and without limitation, the gap 230 may be about 0.25 inches. As a further non-limiting example, the gap 230 may be about 0.5 inches.

FIG. 2B is a partial sectional view of a portion of the gas diffuser support assembly 200 along lines 2B-2B of FIG. 2A. As shown in FIG. 2B, the gas deflector 166 includes a linear arrangement of a plurality of through-holes 255a and 255b. The gas deflector 166 includes a plurality of through-holes 255 to allow for downward vertical gas to proceed through the gas deflector 166. The plurality of through-holes 255 allows for a small portion, e.g., less than a majority of gas such as less than about 50% of gas, or less than about 40% of gas, or less than about 30% of gas, or less than about 20% of gas, or less than about 10% of gas to flow through the plurality of through-holes 255 in the gas deflector 166 and generates downward flow paths 250 that are generally parallel to a longitudinal axis 270 of the backing plate 140 and/or the chamber 100. The plurality of through-holes 255 may originate near the center threaded hole 197 and extend towards an edge of the gas deflector 166 in a radial direction. The through-holes 255 are illustrated in linear arrangements, but non-linear arrangements are also contemplated.

The plurality of through-holes 255 may include any number of through-holes suitable to originate at or near the center threaded hole 197 and proceed towards and edge of the gas deflector 166. For example, and without limitation, the plurality of through holes may include about 2 to about 500 through holes e.g., about 2 to about 250 through-holes, e.g., about 2, about 20, about 40, about 60, about 80, about 90, about 100, about 120, about 130, about 140, about 160, about 180, about 200, about 220, about 240, about 250, or the like. The plurality of through-holes 255 can have a hole size of about 0.01 inches to about 1.0 inches, e.g., about 0.01 inches to about 0.05 inches. For example, and without limitation, the plurality of through-holes 255 can have a hole size of about 0.04 inches, about 0.048 inches, or about 0.05 inches.

The plurality of through-holes 255 has a hole pitch. The hole pitch is a distance from a center of a first through hole 255 to a second through hole 255 in the linear arrangement of a plurality of through-holes 225a. The hole pitch of the plurality of through-holes 255 can have a hole pitch of about 0.125 inches to about 1.5 inches, e.g., about 0.125 inches, about 0.250 inches, about 0.5 inches, about 0.75 inches, about 1 inch, about 1.5 inches, or the like. For example, and without limitation, the plurality of through-holes 255 can have a hole pitch of about 0.25 inches. As a further non-limiting example, the plurality of through-holes 255 can have a hole pitch of about 0.125 inches.

A cover 280 is disposed beneath each head 272 of the fastener of the plurality of fasteners 225 or the center fastener 224, as shown in FIG. 2C. The cover 280 is shown as being transparent, for illustrative purposes, in which any material suitable as a cover to collect and/or prevent particles from the head 272 of the fastener 225 from entering the chamber 225 may be utilized, as shown in FIG. 2C. For example, the cover may be formed of quartz, aluminum, aluminum nitride, or other materials.

The cover 280 includes a main body 290 having tabs 291 on opposing sides thereof. The tabs 291 include an opening 284 for receiving a fasten 282 therein. The fastener(s) 282 secure the cover 280 to a lower surface of the distribution plate 166. A central opening 286 is formed in the cover 280 to receive a fastener (such as fasteners 225 or central fastener 224). The central opening 286 is recessed with respect to a surface 292 of the cover 280 to facilitate countersinking of the head 272 of the fastener. In some aspects, countersinking the head 272 of the fastener may reduce deposition thereon, thus reducing particle contamination. The opening 286 may be round, or oblong as shown. The oblong shape of the opening 286 facilitates alignment of the fastener with an opening formed in the distribution plate 166. An opening 293 is formed at the bottom of the recess 286 to allow passage of the fastener therethrough. Similarly, the opening 293 may be circular or oblong to facilitate alignment. Additionally, the opening 286 includes a shoulder 295 at a bottom thereof. The shoulder surrounds the opening 293 and provides an engagement surface for the fastener. In some examples, transition surfaces 295a, 295 be are chamfered to facilitate guiding of the fastener through the opening 293.

The cover 280 prevents particle contamination of the substrate by collecting one or more particles emitted from the center fastener 224 and/or the plurality of outward fasteners 225, and reducing the likelihood of the particles falling onto a processed substrate. The cover 280 is disposed beneath each fastener 225 of the plurality of fasteners 225 (or the central faster 224), such that the head 272 of the fastener 225 is isolated from the direct gas flow of the gas baffle 168. The head 272 of the fastener 225 rests on the shoulder 294 of the gas deflector 166. The head 272 of the fastener 225 may be sealed on its perimeter by suitable seals (e.g., o-rings) at interfaces where the gas deflector 166 and the cover 280 may contact each other. The cover 280 may protrude from the bottom surface of the gas deflector 166 to collect and prevent particles formed from the center fastener 224, plurality of outward fasteners 225, or head 272 from entering the processing volume of the chamber 100, thereby reducing contamination.

The one or more cover fasteners 282 do not extend into the backing plate 166, resulting in reduced thermal expansion and reduced particle generation from the cover fasteners 282, resulting in reduced particle contamination of the chamber 100. While the foregoing is directed to embodiments of the present disclosure, other and further embodiments of the disclosure may be devised without departing from the basic scope thereof, and the scope thereof is determined by the claims that. follow.

1. A gas diffuser support structure for a vacuum chamber, the gas diffuser support structure comprising:
a backing plate made of a material;
a central bore formed in the backing plate; and
a gas deflector having a length and a width unequal to the length coupled to the backing plate by a plurality of outward fasteners coupled to a plurality of outward threaded holes formed in the backing plate, wherein a spacer is disposed between the backing plate and the gas deflector, and wherein a length to width ratio of the gas deflector is about 0.1:1 to about 10:1.

2. The gas diffuser support structure of claim 1, further comprising a cover coupled to the gas deflector.

3. The gas diffuser support structure of claim 1, wherein the cover is disposed beneath each outward fastener of the plurality of outward fasteners.

4. The gas diffuser support structure of claim 1, wherein the spacer is about 0.1 inches to about 1 inch thick.

5. The gas diffuser support structure of claim 1, wherein the plurality of outward fasteners comprises about 2 to about 20 outward fasteners.

6. The gas diffuser support structure of claim 1, wherein the length to width ratio is about 1.3:1 to about 1.5:1.

7. The gas diffuser support structure of claim 6, wherein the length to width ratio is 1.3:1.

8. The gas diffuser support structure of claim 7, wherein the length to width ratio is 1.5:1.

9. A gas diffuser support structure for a vacuum chamber, the gas diffuser support structure comprising:
a backing plate having a central bore formed therein;
a gas deflector having a length and a width unequal to the length coupled to the backing plate by a plurality of outward fasteners coupled to a plurality of outward threaded holes formed in the backing plate, wherein a length to width ratio of the gas deflector is about 0.1:1 to about 10:1; and
a cover coupled to the gas deflector.

10. The gas diffuser support structure of claim 9, wherein a spacer is disposed between the backing plate and the gas deflector.

11. The gas diffuser support structure of claim 9, wherein the cover is disposed beneath each outward fastener of the plurality of outward fasteners.

12. The gas diffuser support structure of claim 9, wherein the plurality of outward fasteners comprises about 2 to about 20 outward fasteners.

13. The gas diffuser support structure of claim 12, wherein the plurality of outward fasteners is about 8 outward fasteners.

14. The gas diffuser support structure of claim 9, wherein the length to width ratio is about 1.3:1 to about 1.5:1.

15. The gas diffuser support structure of claim 14, wherein the length to width ratio is 1.3:1.

16. The gas diffuser support structure of claim 9, wherein the length to width ratio is 1.5:1.

17. A gas diffuser support structure for a vacuum chamber, the gas diffuser support structure comprising:
a backing plate made of an aluminum material and having a central bore formed therein;
a gas deflector comprising a length and a width unequal to the length coupled to the backing plate by a plurality of outward fasteners coupled to a plurality of outward threaded holes formed in the backing plate, wherein a length to width ratio of the gas deflector is about 0.1:1 to about 10:1; and
a cover coupled to the gas deflector.

18. The gas diffuser support structure of claim 17, wherein the length to width ratio is about 1.3:1 to about 1.5:1.

19. The gas diffuser support structure of claim 18, wherein a spacer is disposed between the backing plate and the gas deflector.

20. The gas diffuser support structure of claim 18, wherein the cover is disposed beneath each outward fastener of the plurality of outward fasteners.
